(19) United States
(12) Patent Application Publication
(10) Pub. No.: US 2018/0351531 A1
(43) Pub. Date: Dec. 6, 2018

(54) ELECTROACOUSTIC TRANSDUCER HAVING FEWER SECOND-ORDER NONLINEARITIES

(71) Applicant: SNAPTRACK, INC., San Diego, CA (US)

(72) Inventors: Werner RUILE, Munich (DE); Markus MAYER, Taufkirchen (DE); Thomas EBNER, Munich (DE)

(21) Appl. No.: 15/778,997

(22) PCT Filed: Nov. 3, 2016
(86) PCT No.: PCT/EP2016/076542

§ 371 Date: May 24, 2018

(30) Foreign Application Priority Data
Nov. 27, 2015 (DE) 10 2015 120 654.4

(51) Int. Cl. H03H 9/02; H03H 9/145

(52) U.S. Cl. CPC H03H 9/02818; H03H 9/14538

(57) ABSTRACT

A transducer with reduced second-order nonlinearities is disclosed. In order to reduce the nonlinearities, the transducer comprises an isolation region between the electrode fingers and the corresponding opposite busbar and a dielectric material for reducing the electric field strength in the isolation region.

### DESCRIPTION

The invention relates to electroacoustic transducers with reduced disturbance due to second-order non-linear effects.

Electroacoustic transducers may be used in RF filters. Arranged together and interconnected, they can form bandpass filters which, due to their small size, are well suited for portable communication devices, for example, in front-end circuits.

Electroacoustic transducers generally comprise metal structures arranged on a piezoelectric material, for example, a monocrystalline substrate, with comb-shaped intermeshing electrode structures with busbars and electrode fingers. Due to the piezoelectric effect, such structures convert between electrical and acoustic waves, wherein half of the acoustic wavelength λ/2 is essentially determined by the spacing of the centers of adjacent electrode fingers of different polarity. The electroacoustically active region of such a transducer, the acoustic trace, comprises the adjacent electrode fingers of opposite polarization.

Stub fingers have previously been used to reduce interfering transverse effects.

For example, from the article “Generation mechanisms of second-order non-linearity in surface acoustic wave devices” (K. Hashimoto, R. Kodaira, T. Omori, 2014 IEEE International Ultrasonics Symposium Proceedings, p. 791), it is known that a nonlinear second-order disturbance may occur at the second harmonic frequency by generating a dielectric displacement D in the transverse direction.

For example, from the article “Effective suppression method for 2nd nonlinear signals of SAW devices” (R. Nakagawa, H. Kyoya, H. Shimizu, T. Kihara, 2014 IEEE International Ultrasonics Symposium Proceedings; p. 782), it is known that such disturbances can be reduced by separating the acoustic trace.

The problem with this improvement in the electrical properties lies in the deterioration of the acoustic properties caused by the separation.

There is therefore a desire for transducers to have not only good electrical properties, in particular reduced second-order nonlinearities, but also good acoustic properties.

The transducer according to claim 1 is proposed for this purpose. Dependent claims specify advantageous embodiments.

The electroacoustic transducer comprises a piezoelectric material, two busbars arranged side by side and aligned parallel on the piezoelectric material, and electrode fingers disposed between the busbars for exciting acoustic waves. The electrode fingers are each connected to one of the two busbars. The transducer further comprises an isolation region which is arranged between the electrode fingers and the respective other, opposite busbar and galvanically separates the electrode fingers from this opposite busbar. Furthermore, the transducer has a dielectric material for reducing the electric field strength in the isolation region.

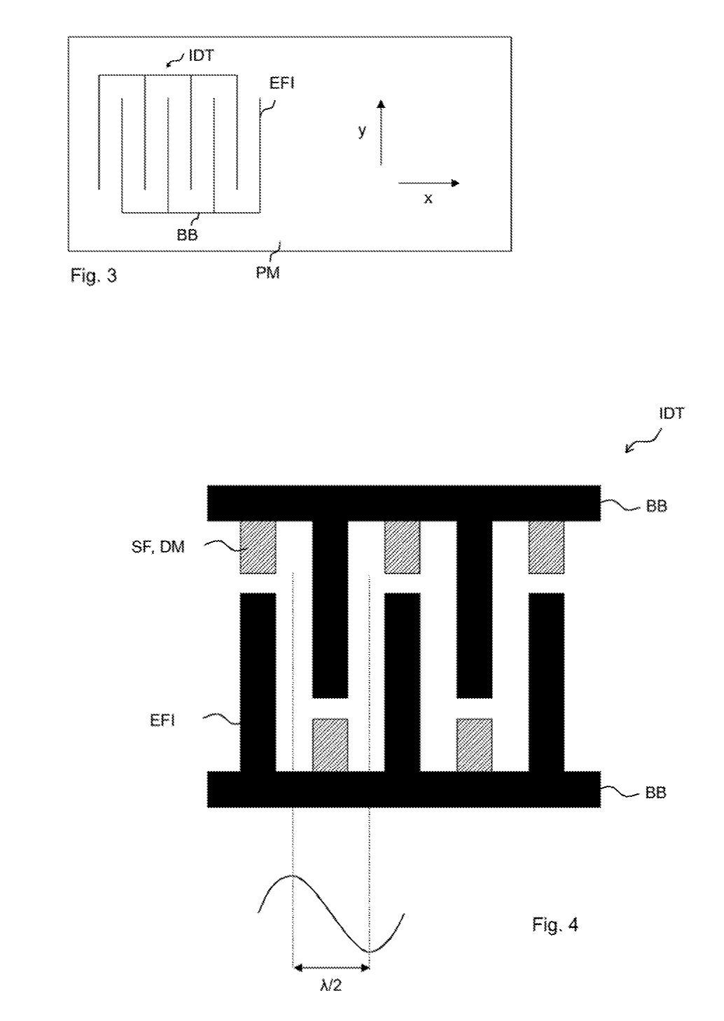

FIG. 3 shows the fundamental arrangement of the busbars and the electrode fingers relative to the propagation direction x of the acoustic waves. The one side of each electrode finger is connected with one of the two busbars. On the other side, they are isolated from the opposite busbar in order to prevent an electrical short circuit. Adjacently arranged electrode fingers, and correspondingly the two opposite busbars, are at different electrical potentials. Corresponding to the associated electrical charges accumulated on the electrode structures, electric fields are present between the oppositely charged structures. In the area between the electrode structures, the field strength is reciprocal to the distance d:

$$\vert \vec{E} \vert ∝ \frac{1}{d} \qquad ( 1 )$$

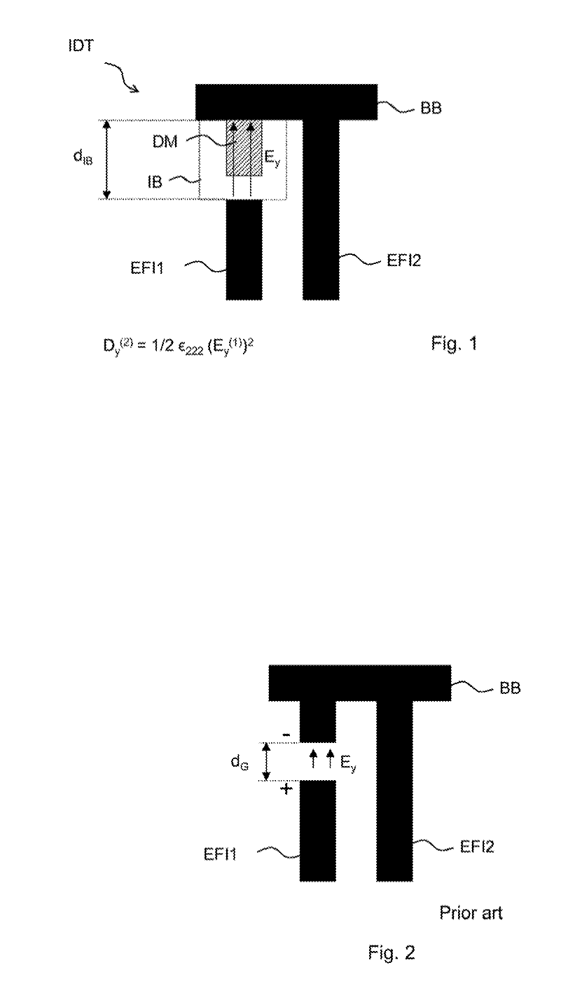

FIG. 2 shows the corresponding portion of the transducer and illustrates the problem: In conventional transducers, finger stubs are connected to the busbars in addition to the conventional electrode fingers. The distance between a stub finger and the electrode finger of the opposite electrode is labeled d_{G}. When the transducer is in operation, an electric field is present between these metallizations, having a strength in the y-direction that is reciprocal to the distance:

$$\vert {E}_{y} \vert ∝ \frac{1}{{d}_{G}} \qquad ( 2 )$$

The area between the ends of the stub fingers and the ends of the opposite electrode fingers is referred to as a “gap.”

Nonlinear disturbances arise due to the tensor of the permittivity having a non-zero component ε_{yyy}. This results in the component E_{y} of the electric field causing a component of the dielectric displacement D_{y} applied in the y direction:

D_{y}⁽²⁾1/2ϵ_{yyy}(E_{y}⁽¹⁾)² (3)

This component of the dielectric displacement is proportional to the square of the component of the electric field, and a variation in time of the electric field therefore causes a variation in time of the dielectric displacement with twice the frequency.

Compared with the known transducer structures of FIG. 2, the present transducer has the isolation region with the dielectric material between the electrode fingers, in particular the ends of the electrode fingers of the one electrode, and of the other, in each case opposite busbar. Viewed in the y-direction in the place of the otherwise usual stub finger, the spatial distance between the ends of the one electrode finger and the charge-carrying metallization of the opposite busbar is thereby increased. With the same difference in the charge densities and with increased distance, the electric field strength is correspondingly reduced. Accordingly, the component of the dielectric displacement in the transverse direction D_{y} is correspondingly reduced, whereby the second-order disturbances caused by it are reduced as well.

A typical ratio of stub finger length and width of the gap D_{G} is about 4/5:1/5. By appropriate quintupling of the distance of the oppositely charged electrode structures, a reduction of the resulting second-order disturbances by the factor 5²=25 can thus be achieved.

Replacing the stub fingers by an isolation region with dielectric material has the disadvantage that the processing steps to manufacture the transducer require additional effort. Compared with the trivial solution of dispensing with the stub fingers, the acoustic properties of the transducer are improved.

The piezoelectric material may be a piezoelectric substrate.

An advantage of a transducer in which the region that is defined by the designation “gap,” in conventional transducers is filled by the dielectric material is the reduction of the transverse electric field strength in the substrate and the associated nonlinearity and reduction of the excitation of acoustic waves in the gap. The dielectric material on the substrate extracts field strength from the substrate. However, the parasitic total capacitance may be increased as a result. The decisive factor is the change in the substrate.

It is possible and advantageous for the dielectric material to reduce the electric field strength E in the transverse direction in the piezoelectric material, for example, in a monocrystalline substrate, during operation of the transducer.

The transverse direction is orthogonal to the propagation direction of the acoustic waves, the longitudinal direction, and parallel to the surface of the piezoelectric material. The electrode fingers point essentially in the transverse direction.

It is therefore also possible and advantageous for the dielectric material to reduce the dielectric displacement D in the transverse direction in the substrate during operation of the transducer.

The dielectric material may comprise multiple layers. The layers may comprise different materials, have different lateral dimensions, and/or have different thicknesses.

The dielectric material may be structured as a stub finger in the isolation region.

It is alternatively possible for the dielectric material to be structured as a finger that connects the electrode fingers to the respectively opposite busbar, but is galvanically isolated from the latter.

Alternatively, the dielectric material may also be structured in two continuous strips along the two busbars and be arranged on the piezoelectric material and on the electrode fingers.

The dielectric material may have fingers whose density, width, and height are chosen such that the reflection of these dielectric fingers resembles, or is identical to, the reflection of the other electrode fingers. The better the acoustic impedance of the dielectric material is matched to the acoustic impedance of the other electrode fingers, the better, that is to say, the less disturbed, the acoustic waves can propagate.

The dielectric material may have fingers that overlap electrode fingers of the opposing busbar in an overlap region and the dielectric material may be arranged on the electrode fingers in the overlap region.

The dielectric material may also have fingers that overlap electrode fingers of the opposing busbar in an overlap region and the electrode fingers may be arranged on the dielectric material in the overlap region.

If the dielectric material is located in the overlap region between the piezoelectric material and the electrode fingers, the piezoelectric coupling between the electrode fingers and the piezoelectric material is reduced, while the acoustic coupling ideally remains unchanged by the presence of the material of the electrode fingers. The propagation of the acoustic waves can thus be improved because the excitation of the acoustic waves at the finger ends is reduced and an excitation profile can thus be obtained that better corresponds to the propagation profile of the acoustic waves.

However, even an overlap in which the dielectric material is arranged on the electrode fingers is advantageous since such an overlap is easier to implement from a manufacturing standpoint than are flush terminations of the corresponding materials at the interface.

The transducer may also include a material layer for temperature compensation. The temperature compensation material layer covers the exposed upper surfaces of the electrode fingers, the exposed upper surfaces of the piezoelectric material, and the exposed upper surfaces of the dielectric material. The acoustic impedance of the material layer for temperature compensation differs from the acoustic impedances of the electrode fingers and the dielectric material.

The piezoelectric material may comprise LiNbO₃ (lithium niobate).

The LiNbO₃ may have the red-128YX crystal cut.

The material of the electrode fingers may comprise Al (aluminum) as a main component. The dielectric material may be SiO₂ (silicon dioxide).

The piezoelectric material may comprise LiTaO₃ (lithium tantalate).

The LiTaO₃ may have the YX1/42 crystal cut, according to the IEEE definition for crystal cuts.

The material of the electrode fingers may comprise Cu (copper) as a main component. The dielectric material may comprise Ta₂O₅ (tantalum oxide) or GeO₂ (germanium oxide) as a main component.

Other piezoelectric materials, such as quartz, are also possible.

Alternatively, the dielectric material may be the same material as the piezoelectric material that is also used as a carrier substrate beneath the electrode structures.

The latter is possible and can be achieved by the electrode structures and the dielectric material being embedded or arranged in correspondingly formed recesses on the upper surface of the piezoelectric material.

In one embodiment that is improved by good acoustic impedance matching, the height of the electrode fingers is 8% of the acoustic wavelength, A. The width of the electrode fingers is 60% of half the acoustic wavelength, λ/2, corresponding to a metallization ratio r of 60%. The dielectric material has fingers with a height of 14% of the acoustic wavelength, λ. The width of the fingers of the dielectric material is 60% of half the acoustic wavelength, λ/2.

In addition to the reflection, the propagation velocity of the acoustic wave in the region of the dielectric material is advantageously matched to the reflection and the velocity of the wave in the central excitation region in the center between the busbars by the dimensioning of the height, the width, and the acoustic impedance of the dielectric material.

To achieve the matching with respect to the reflection and acoustic velocity adjustment, fingers of the dielectric material may have a width or height that is different from the corresponding width or height of the finger electrodes.

The electrode fingers and the structure of the dielectric material need not necessarily be homogeneous, i.e., constant over the longitudinal propagation direction. Along the propagation direction of the acoustic waves, the finger widths and the finger distances may vary, as in the case of RSPUDT (RSPUDT=Resonant SPUDT [Single Phase Unidirectional Transducer]) filters.

The dielectric material in the isolation region may be structured such that the lower stopband edges of the waveguide formed by the electrode fingers and of the waveguide formed by the structures of the dielectric material match.

To this end, the height of the dielectric material may, for example, be adjusted such that the lower stopband edges of the waveguide formed by the electrode fingers and of the waveguide formed by the structures of the dielectric material match.

Functional principles of the transducer and exemplary embodiments are shown below with reference to schematic figures.

Shown are:

FIG. 1: The functional principle of the dielectric material in the isolation region,

FIG. 2: The problem of conventional transducers,

FIG. 3: The arrangement of a transducer on a piezoelectric material and the alignment of the electrode fingers and the busbars relative to the propagation direction x of the acoustic waves,

FIG. 4: An embodiment with dielectric material in the form of stub fingers,

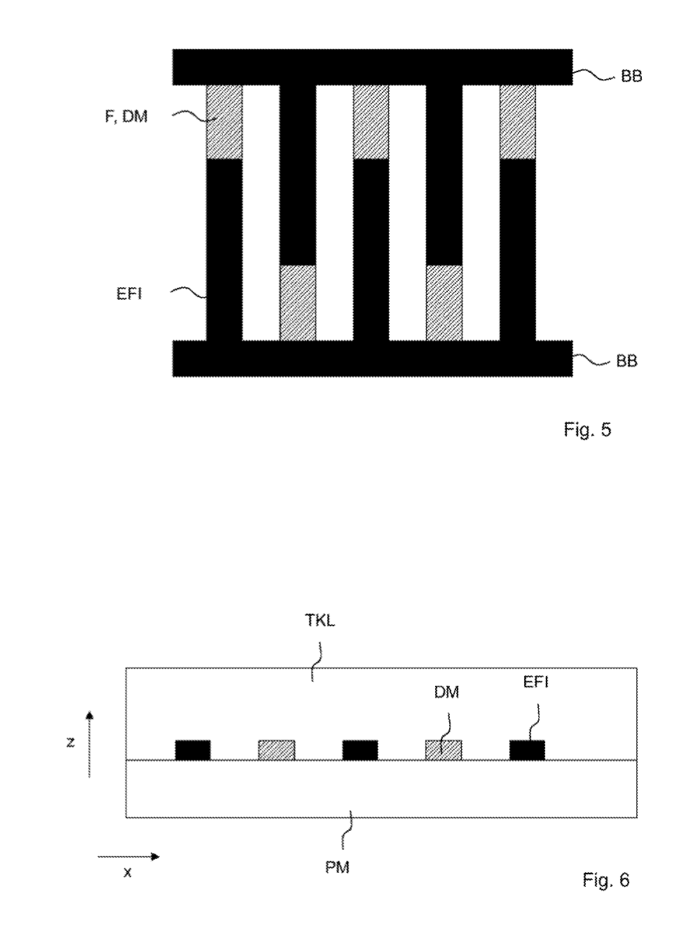

FIG. 5: An embodiment with fingers of dielectric material that in flush contact with the electrode fingers,

FIG. 6: A cross-section through a transducer with a temperature compensation layer,

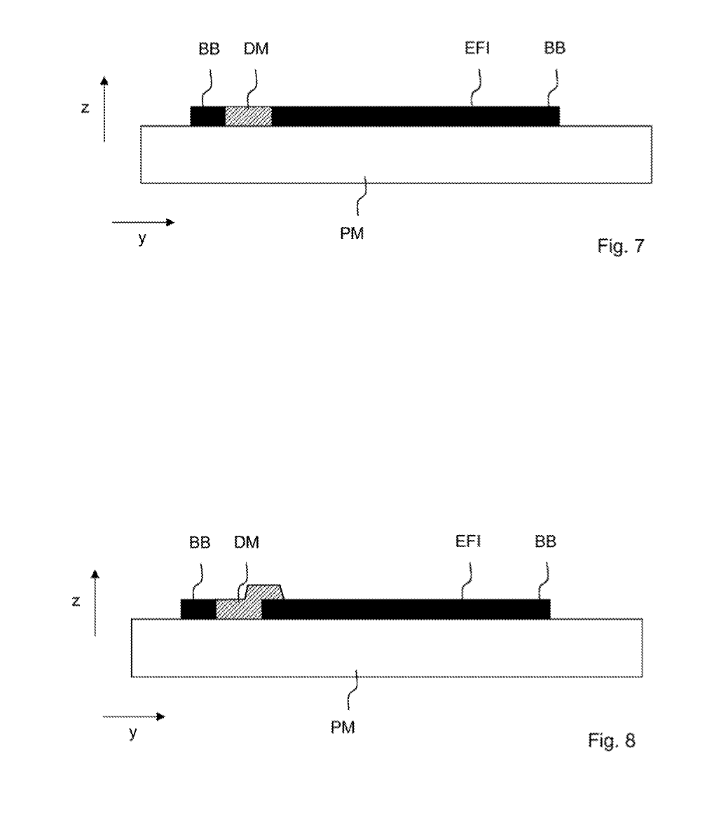

FIG. 7: A cross-section through the yz plane in an embodiment in which the dielectric material is structured flush with the corresponding electrode finger,

FIG. 8: A cross-section through the yz plane, in which the dielectric material and the material of the electrode fingers overlap and the metal of the electrode fingers is arranged under the dielectric material in the overlap region,

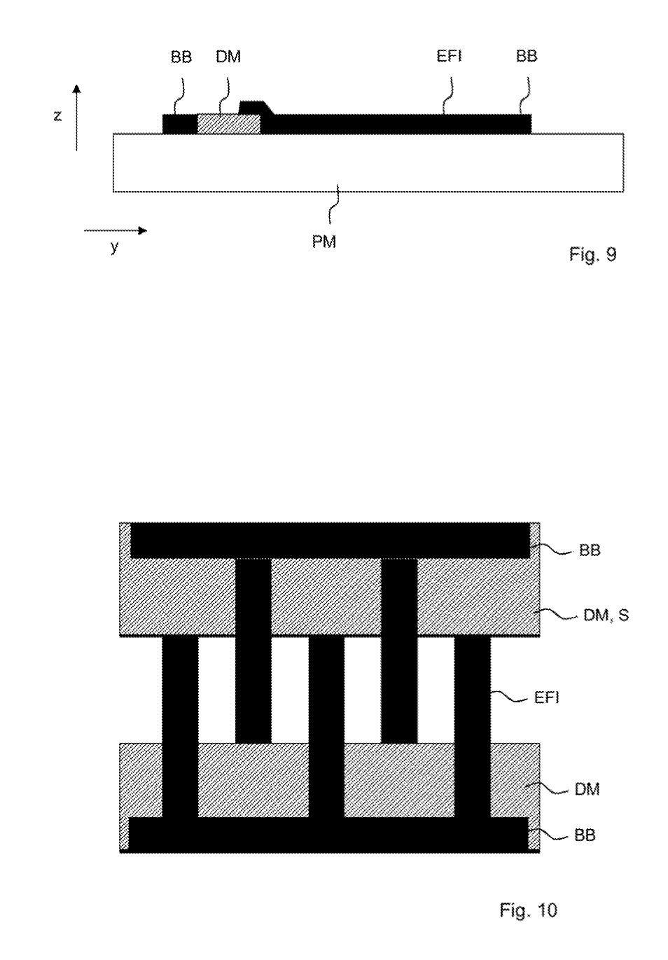

FIG. 9: A cross-section through the yz plane of an embodiment in which the dielectric material and the electrode fingers overlap and the dielectric material is arranged between the metal of the electrode fingers and the piezoelectric material,

FIG. 10: An embodiment in which the dielectric material is structured in two strips along the longitudinal propagation direction,

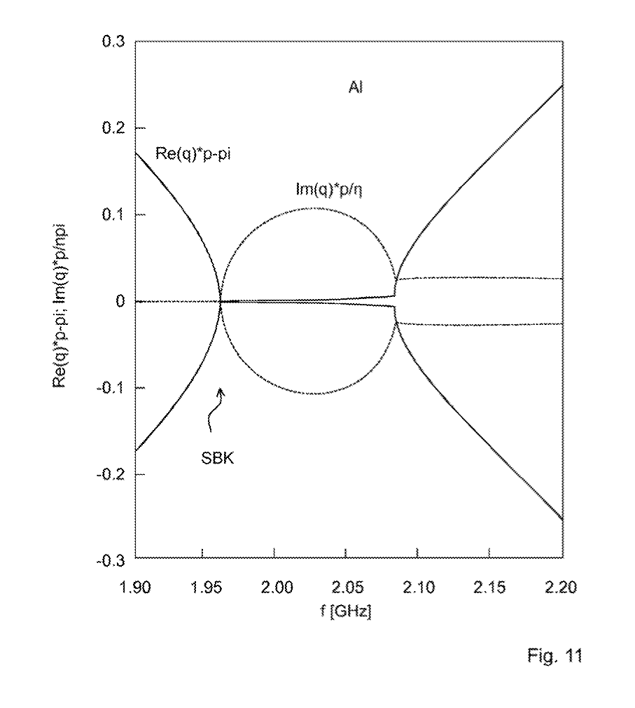

FIG. 11: The real part and the imaginary part of the dispersion relation of an electrode finger made of aluminum,

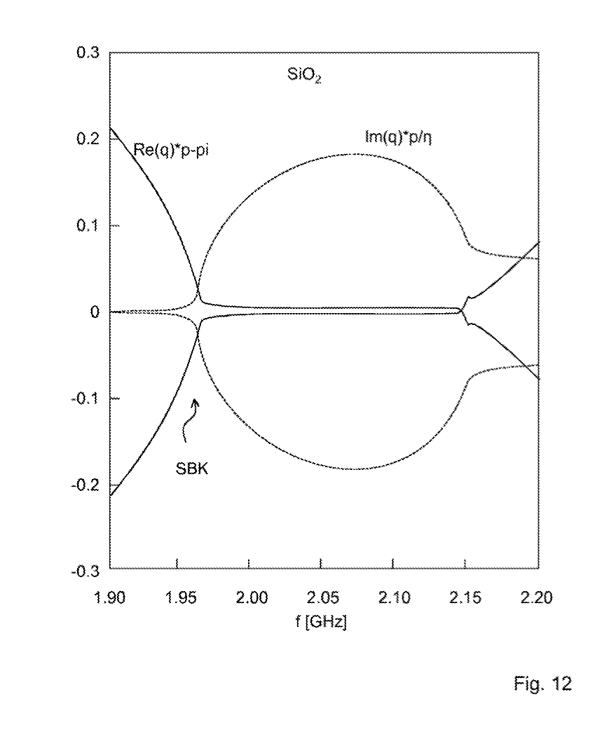

FIG. 12: The real part and the imaginary part of the dispersion relation of a waveguide having finger structures made of silicon dioxide.

FIG. 1 shows the mode of action of the dielectric material DM in the isolation region IB of an electroacoustic transducer IDT against the background of a conventional transducer shown in FIG. 2: The distance of an electrode finger EFI1 from conductive material connected to the opposite busbar—and thus the width d_{IB} of the isolation region—is increased, for example, quintupled, by the provision of the dielectric material DM without substantially affecting the acoustic properties. This reduces the field strength E_{y}, to a fifth in the numerical example, if d_{iB}=5 d_{G}. The quadratic dependence of the dielectric displacement on the electric field results in a reduction of the interference at twice the frequencies due to the non-zero tensor component ε_{yyy}; accordingly, the numbers in the parentheses of the equation shown denote multiples of the fundamental frequency.

Correspondingly, FIG. 2 shows a conventional transducer in which a relatively strong electric field is effective in the transverse direction E_{y} due to a markedly small distance dg.

FIG. 3 shows the orientation of the electroacoustic transducer IDT, its busbars BB, and its electrode fingers EFI relative to the propagation direction of the acoustic waves x and the transverse direction y. The busbars BB and the electrode fingers EFI are arranged and aligned on a piezoelectric material PM such that the highest possible electroacoustic coupling coefficient K² is achieved. For this purpose, the intersection angle of the piezoelectric material, which generally consists of a monocrystalline piezoelectric wafer, is selected.

FIG. 4 shows an embodiment of the transducer IDT in which the dielectric material is arranged between the ends of the electrode fingers EFI and the opposite busbar BB in the form of stub fingers SF.

It should be noted that the isolation region does not need to be contiguous. Similarly, the dielectric material does not need to consist of a single aggregate. The dielectric material may be distributed among the corresponding locations of the finger ends of the electrode fingers.

The dielectric material may consist of different layers, for example, to obtain good acoustic impedance matching. A combination with methods for the optimization of other parameters can thus be achieved without additional overhead in manufacturing.

Half the acoustic wavelength, λ/2, is determined by the distance between two adjacent excitation centers. One excitation center lies in the center between two electrode fingers of different potential.

FIG. 5 shows an embodiment in which the so-called “gaps” are completely filled by finger-shaped structured sections F of the dielectric material DM. E

FIG. 6 shows a cross-section through the xz plane, the coordinate z indicating the height. The exposed surfaces of the piezoelectric material PM, the exposed surfaces of the electrode fingers EFI, and the exposed surfaces of the dielectric material DM are covered by the material of a temperature compensation layer TKL to ensure functioning of the electroacoustic transducer within predetermined specifications over a wide temperature range. The material of the temperature compensation layer TKL and the piezoelectric material PM are matched to one another such that temperature responses of the frequencies are reduced and ideally compensated.

For the dielectric material to be able to contribute to forming an acoustic conductor together with the electrode fingers EFI, the acoustic impedances of the dielectric material and the electrode fingers are preferably very similar, and ideally identical, but different from the acoustic impedance of the temperature compensation layer TKL.

FIG. 7 shows a cross-section through the yz plane of an embodiment in which the dielectric material between the busbar BB and the opposite electrode finger EFI adjoins flush with this electrode finger EFI, so that—with appropriate dimensioning of the height, width and the acoustic impedance of the dielectric material—an ideal waveguide is obtained.

FIG. 8 shows a cross-section through the yz plane of an embodiment that is simpler to manufacture in which the dielectric material and the opposing electrode finger EFI at least partially overlap, with the dielectric material DM being arranged on the upper surface of the piezoelectric material PM and, in the overlap region, on the upper surface of the electrode finger EFI.

FIG. 9 shows a cross-section through the yz plane of a more easily manufactured embodiment, in which, similarly to the embodiment of FIG. 8, the dielectric material DM and the electrode fingers EFI are arranged one above the other in an overlap region. In the embodiment shown in FIG. 9, the dielectric material DM is disposed beneath the material of the electrode finger EFI in the overlap region. This reduces electroacoustic coupling in the overlap region. The acoustic waveguide properties can thus be further improved.

FIG. 10 shows an embodiment in which the dielectric material is arranged over a large area in strips on the upper surface of the piezoelectric material aligned in parallel with the busbars BB. The dielectric material may be distributed through the material of the electrode fingers on different non-contiguous areas.

However, the dielectric material of a single strip may also be applied over a large area over the corresponding portion of the electrode finger, which simplifies manufacturing. For the sake of clarity, the dielectric material in the region of the electrodes is shown as transparent in FIG. 10.

FIG. 11 shows the real part (solid line) and the imaginary part (broken line) of the dispersion relation of a waveguide (for example, the acoustically active region) with electrode fingers made of aluminum, weighted by the pitch p. The imaginary part is additionally normalized to the metallization ratio η.

The stopband edge SBK at about 1.98 GHz is characterized by a decreasing real part and by a growing imaginary part.

FIG. 12 shows the corresponding curves for a waveguide (for example, of the isolation region) with finger structures made of silicon dioxide, where the lower stopband edge SBK is also around 1.98 GHz.

FIGS. 11 and 12 thus show waveguide structures the lower stopband edges of which are matched to improve wave propagation with reduced nonlinearities throughout the transducer.

The curves 11 and 12 thus clearly show that finger structures made of aluminum and silicon dioxide can be dimensioned so that they can be used together in an acoustic trace. Thus, silicon dioxide can be easily used as the dielectric material for reducing the electric field strength to reduce second-order nonlinear disturbances.

The transducer is not limited to the described or shown embodiments. Transducers having other structures for improving waveguide properties or for reducing electrical disturbances are also included in embodiments of the invention.

### LIST OF REFERENCE SIGNS

BB: busbar
d_{IB}: width of isolation region IB
d_{G}: width of gap
DM: dielectric material
D_{y}: component of the dielectric displacement
EFI1, EFI2, EFI: electrode finger
E_{y}: component of the electric field
F: finger
f: frequency
IB: isolation region
IDT: transducer
p: pitch
PM: piezoelectric material
q: wave number
S: strip
SBK: stopband edge
SF: stub finger
TKL: temperature compensation length
x: propagation direction of the acoustic waves
y: transverse direction
z: height
ϵ_{yyy}:tensor component of permittivity
η: metallization ratio
λ: acoustic wavelength

1. An electroacoustic transducer (IDT) with reduced second-order nonlinearities, comprising
a piezoelectric material (PM),
two busbars (BB), arranged side by side and aligned in parallel on the piezoelectric material (PM),
electrode fingers (EF) arranged between the busbars (BB) for exciting acoustic waves, each of which is connected to one of the two busbars (BB),
an isolation region (IB) which is arranged between the electrode fingers (EF) and the corresponding other, opposite busbar (BB) and galvanically separates the electrode fingers (EF) from this busbar (BB),
a dielectric material (DM) for reducing the electric field strength in the isolation region (IB);
wherein the dialectric material (DN) is structured as a stub finger (SM) in the insulation region (IB).

2. The transducer according to the preceding claim, wherein the dielectric material (DM) reduces the electric field strength in the piezoelectric material (PM) in the transverse direction during operation of the transducer (IDT).

3. The transducer according to any one of the preceding claims, wherein the dielectric material (DM) reduces the dielectric displacement in the piezoelectric material (PM) in the transverse direction during operation of the transducer.

4. The transducer according to any one of the preceding claims, wherein the dielectric material (DM) comprises multiple layers.

5. (canceled)

6. The transducer according to any one of claims 1 to 4, wherein the dielectric material (DM) is structured as fingers (F) that connect the electrode fingers (EF) to the corresponding opposite busbar (BB) and galvanically isolate them.

7. The transducer according to any one of claims 1 to 4, wherein the dielectric material (DM) is structured in two continuous strips (S) along the two busbars (BB) and arranged on the piezoelectric material (PM) and on the electrode fingers (EF).

8. The transducer according to any one of the preceding claims, wherein the dielectric material (DM) has fingers (F), the density, width, and height of which are chosen such that the reflection of these dielectric fingers (F) equals the reflection of the electrode fingers (EF).

9. The transducer according to any one of the preceding claims, wherein the dielectric material (DM) has fingers (F), the density, width, and height of which are chosen such that the acoustic velocity in the isolation region (IB) equals the acoustic velocity in the region of the electrode fingers (EF).

10. The transducer according to any one of the preceding claims, wherein the dielectric material (DM) has fingers (F) that overlap with electrode fingers (EF) of the opposite busbar (BB) in an overlap region and the dielectric material (DM) is arranged on the electrode fingers (EF) in the overlap region.

11. The transducer according to any one of claims 1 to 9, wherein the dielectric material (DM) has fingers (F) that overlap with electrode fingers (EF) of the opposing busbar (BB) in an overlap region and the electrode fingers (EF) are arranged on the dielectric material (DM) in the overlap region.

12. The transducer according to any one of the preceding claims, further comprising a material layer (TKL) for temperature compensation, covering the electrode fingers (EF), the piezoelectric material (PM), and the dielectric material (DM) and having an acoustic impedance different from the acoustic impedances of the electrode fingers (EF) and of the dielectric material (DM).

13. The transducer according to any of the preceding claims, wherein
the piezoelectric material (PM) comprises LiNbO₃,
the material of the electrode fingers (EF) comprises Al as the main component, and
the dielectric material (DM) comprises SiO₂ as the main component.

14. The transducer according to the preceding claim, wherein the piezoelectric material (PM) LiNbO₃ has the red XY 128 crystal cut.

15. The transducer according to any one of the preceding claims, wherein the piezoelectric material (PM) comprises LiNbO₃,
the material of the electrode fingers (EF) comprises Cu,
the dielectric material (DM) comprises a material selected from: Ta₂O₅, GeO₂, a piezoelectric material.

16. The transducer according to the preceding claim, wherein the piezoelectric material (PM) LiTaO₃ has the YXI/42 crystal cut.

17. The transducer according to any of the preceding claims, wherein
the height of the electrode fingers (EF) is 8% of the acoustic wavelength λ, and the width of the electrode fingers (EF) is 60% of half the acoustic wavelength λ/2,
the dielectric material (DM) includes fingers (F), the height of which is 14% of the acoustic wavelength λ and the width of which is 60% of half the acoustic wavelength λ/2.

18. The transducer according to any one of the preceding claims, wherein the dielectric material (DM) in the isolation region (IB) is structured such that the lower stopband edges of the waveguide formed by the electrode fingers (EF) and of the waveguide formed by the dielectric material (DM) match.
